(19) United States
(12) Patent Application Publication
(10) Pub. No.: US 2011/0127636 A1
(43) Pub. Date: Jun. 2, 2011

(54) INTEGRATED PASSIVE DEVICE ASSEMBLY

(75) Inventors: Sang Wook PARK, Gyunggi-do (KR); Chul Hwan YOON, Gyunggi-do (KR); Youn Suk KIM, Gyunggi-do (KR); Seong Geun KIM, Gyunggi-do (KR); Sang Hee KIM, Seoul (KR); Jae Hyouck CHOI, Gyunggi-do (KR)

(73) Assignee: SAMSUNG ELECTRO-MECHANICS CO., LTD., Gyunggi-do (KR)

(21) Appl. No.: 12/851,181

(22) Filed: Aug. 5, 2010

(30) Foreign Application Priority Data
Nov. 27, 2009 (KR) 10-2009-0115664

(51) Int. Cl. H01L 23/48

(52) U.S. Cl. 257/528; 257/734; 257/E23.01

(57) ABSTRACT

There is provided an integrated passive device assembly including: a substrate having a wiring pattern disposed therein; a mounting part disposed on an upper surface of the substrate, formed of an insulating material, and having an integrated passive device mounted on an upper surface thereof; a conductive pattern disposed inside the mounting part; and a connecting part disposed on the substrate and electrically connected to the integrated passive device. The connecting part and the conductive pattern are electrically connected to the wiring pattern.

### CROSS-REFERENCE TO RELATED APPLICATIONS

This application claims the priority of Korean Patent Application No. 10-2009-0115664 filed on Nov. 27, 2009, in the Korean Intellectual Property Office, the disclosure of which is incorporated herein by reference.

### BACKGROUND OF THE INVENTION

1. Field of the Invention

The present invention relates to an integrated passive device (IPD) assembly, and more particularly, to an IPD assembly having high space utilization and high reliability.

2. Description of the Related Art

An integrated passive device (IPD) is an integrated device allowing for the integrated mounting of wireless communication components or passive circuit components, such as a resistor, an inductor, or a capacitor, which are used in an optoelectronic integrated circuit system, on a single small-sized semiconductor substrate.

IPD technology decreases circuit size and increases RF characteristics by integrating individual passive devices for which high levels of integration have conventionally been disadvantageous due to technical restrictions in a system using RF electronic components.

Such an IPD is generally mounted on a mounting part by using an adhesive, in which the mounting part is formed of metal and disposed on the upper surface of a wiring substrate.

When the mounting part on which the IPD is mounted is formed of metal, it does not serve any function. Accordingly, space utilization is reduced.

Further, when the IPD is attached to the mounting part formed of metal by using the adhesive, adhesive strength is insufficient.

### SUMMARY OF THE INVENTION

An aspect of the present invention provides an integrated passive device assembly allowing for high space utilization by increasing the usefulness of a mounting part on which an integrated passive device is mounted.

An aspect of the present invention also provides an integrated passive device assembly having improved reliability by preventing an adhesive used when an integrated passive device is mounted from flowing into a connecting part.

According to an aspect of the present invention, there is provided an integrated passive device assembly including: a substrate having a wiring pattern disposed therein; a mounting part disposed on an upper surface of the substrate, formed of an insulating material, and having an integrated passive device mounted on an upper surface thereof; a conductive pattern disposed inside the mounting part; and a connecting part disposed on the substrate and electrically connected to the integrated passive device. The connecting part and the conductive pattern are electrically connected to the wiring pattern.

The integrated passive device may be mounted on the mounting part using an adhesive. The mounting part and the connecting part may have a groove disposed therebetween in order to prevent the adhesive from flowing into the connecting part.

The integrated passive device assembly may further include a via provided inside the substrate. The via may electrically connect the connecting part and the conductive pattern to the wiring pattern.

The conductive pattern may be employed as a passive device.

The connecting part may include a conductive layer having a predetermined area on the upper surface of the substrate; and a protective layer exposing a portion of the conductive layer on the conductive layer, formed of an insulating material, and protecting the conductive layer. The integrated passive device may be connected to the exposed conductive layer by a wire.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating an integrated passive device assembly according to an exemplary embodiment of the present invention;

FIG. 2 is a cross-sectional view illustrating an integrated passive device assembly according to another exemplary embodiment of the present invention; and

FIG. 3 is a view schematically illustrating a configuration of the IPD assembly according to the exemplary embodiment shown in FIG. 1 or 2 in terms of functionality.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In describing the present invention, if a detailed explanation for a related known function or construction is considered to unnecessarily divert from the gist of the present invention, such explanation will be omitted but would be understood by those skilled in the art.

Throughout the drawings, the same reference numerals will be used to designate the same or like elements.

In addition, throughout the disclosure, when one element is referred to as being “connected” to another element, it should be understood that the former can be “directly connected” to the latter, or “indirectly connected” to the latter via an intervening element. Furthermore, unless explicitly described to the contrary, the word “include” and variations such as “includes” or “including,” will be understood to imply the inclusion of stated elements but not the exclusion of any other elements.

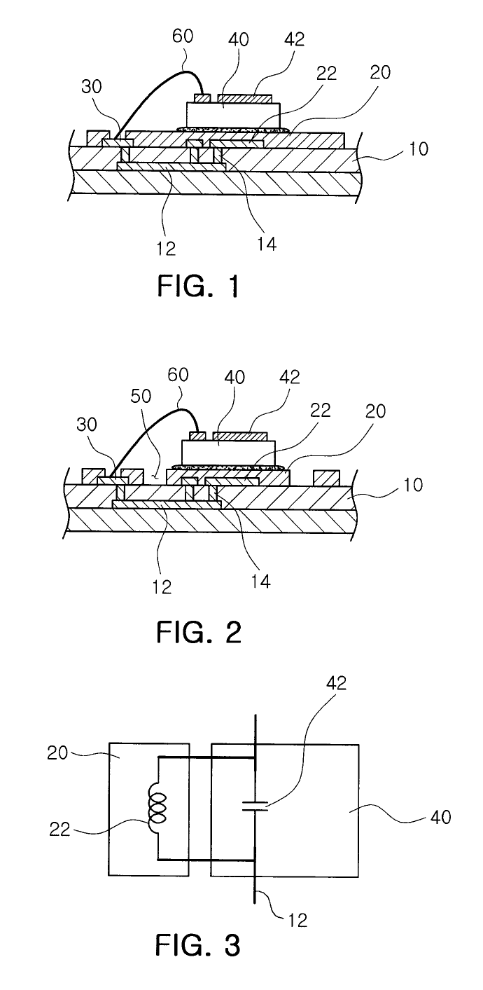

FIG. 1 is a cross-sectional view illustrating an integrated passive device (IPD) assembly according to an exemplary embodiment of the present invention.

Referring to FIG. 1, an IPD assembly according to an exemplary embodiment of the invention may include a substrate 10, a mounting part 20, a connecting part 30, and an IPD 40.

The substrate 10 may be a single-layer or multi-layer printed circuit board (PCB) in which a wiring pattern 12 is formed. Also, the substrate 10 may have a plurality of vias 14 formed therein.

The mounting part 20 provides an area on which the IPD 40 is mounted. The mounting part 20 is formed of an insulating material such that the IPD 40 may be firmly attached to the mounting part 20 when the IPD 40 is mounted thereon by using an adhesive.

A conductive pattern 22 may be formed inside the mounting part 20. The conductive pattern 22 may be employed as a passive device such as a resistor, an inductor, or a capacitor. In this manner, the mounting part, which conventionally does not serve any function, functions as a passive device, thereby achieving a high degree of space utilization.

The connecting part 30 may be electrically connected to the IPD 40 by a wire 60. Here, the connecting part 30 may include a conductive layer having a predetermined area on the upper surface of the substrate 10 and a protective layer exposing a portion of the conductive layer and formed of an insulating material.

The connecting part 30 and the conductive pattern 22 may electrically connected to the wiring pattern 12 by the plurality of vias 14 formed inside the substrate 10.

That is, the IPD 40 and the conductive pattern 22 are electrically connected to the wiring pattern 12 formed inside the substrate 10, thereby forming a circuit including a passive device.

The IPD 40 may be realized by forming a conductive pattern 42 employed as a passive device such as a resistor, an inductor, or a capacitor on the upper surface of a substrate such as a semiconductor substrate.

FIG. 2 is a cross-sectional view illustrating an IPD assembly according to another exemplary embodiment of the present invention.

Referring to FIG. 2, an IPD assembly according to another exemplary embodiment of the invention is the same as that according to the embodiment of the invention as shown in FIG. 1, except that a groove 50 is formed between the connecting part 30 and the mounting part 20. Accordingly, a detailed description of the same parts will be omitted below.

The IPD assembly according to another exemplary embodiment of the invention shown in FIG. 2 includes the groove 50 having a predetermined depth and being disposed between the connecting part 30 and the mounting part 20. The groove 50 prevents an adhesive used when the IPD 40 is mounted on the mounting part 20 from flowing into the connecting part 30.

The connecting part 30 is bonded to the wire 60 for the electrical connection with the IPD 40. In the case that foreign objects such as the adhesive flow into the connecting part 30, this may cause a problematic electrical connection between the connecting part 30 and the IPD 40, thereby degrading reliability.

However, the IPD assembly shown in FIG. 2 may include the groove 50 in order to prevent the adhesive from flowing into the connecting part 30, thereby improving reliability.

FIG. 3 is a view schematically illustrating a configuration of the IPD assembly according to the exemplary embodiment shown in FIG. 1 or 2 in terms of functionality.

Referring to FIG. 3, the conductive pattern 22 formed inside the mounting part 20 of the IPD assembly may function as an inductor, and the conductive pattern 42 formed on the upper surface of the IPD 40 may function as a capacitor. Here, the conductive patterns 22 and 42 that are respectively employed as the inductor and the capacitor may be merely a single example of a passive device used in this invention. Each of the conductive patterns 22 and 42 may be one of a resistor, an inductor, or a capacitor.

The conductive patterns 22 and 42 having the functions of the inductor and the capacitor may be electrically connected to the wiring pattern 12 formed inside the substrate 10, thereby forming a passive device circuit.

As set forth above, according to exemplary embodiments of the invention, an IPD assembly has a conductive pattern formed inside a mounting part on which an IPD is mounted, thereby increasing a total space utilization.

Also, since a mounting part is formed of an insulating layer, the mounting part may have an IPD mounted thereon with being strongly attached thereto using an adhesive.

While the present invention has been shown and described in connection with the exemplary embodiments, it will be apparent to those skilled in the art that modifications and variations can be made without departing from the spirit and scope of the invention as defined by the appended claims.

What is claimed is:

1. An integrated passive device assembly comprising:
a substrate having a wiring pattern disposed therein;
a mounting part disposed on an upper surface of the substrate, formed of an insulating material, and having an integrated passive device mounted on an upper surface thereof;
a conductive pattern disposed inside the mounting part; and
a connecting part disposed on the substrate and electrically connected to the integrated passive device,
wherein the connecting part and the conductive pattern are electrically connected to the wiring pattern.

2. The integrated passive device assembly of claim 1, wherein the integrated passive device is mounted on the mounting part using an adhesive, and
the mounting part and the connecting part have a groove disposed therebetween in order to prevent the adhesive from flowing into the connecting part.

3. The integrated passive device assembly of claim 1, further comprising a via provided inside the substrate,
wherein the via electrically connects the connecting part and the conductive pattern to the wiring pattern.

4. The integrated passive device assembly of claim 1, wherein the conductive pattern is employed as a passive device.

5. The integrated passive device assembly of claim 1, wherein the connecting part comprises:
a conductive layer having a predetermined area on the upper surface of the substrate; and
a protective layer exposing a portion of the conductive layer on the conductive layer, formed of an insulating material, and protecting the conductive layer,
wherein the integrated passive device is connected to the exposed conductive layer by a wire.
